(19) United States
(12) Patent Application Publication
(10) Pub. No.: US 2026/0190225 A1
(43) Pub. Date: Jul. 2, 2026

(54) CIRCUIT BOARD ASSEMBLY

(71) Applicants: FOXCONN (KUNSHAN) COMPUTER CONNECTOR CO., LTD., Kunshan (CN); FOXCONN INTERCONNECT TECHNOLOGY LIMITED, Grand Cayman (KY)

(72) Inventor: FANG-JWU LIAO, New Taipei (TW)

(21) Appl. No.: 19/437,893

(22) Filed: Dec. 31, 2025

(30) Foreign Application Priority Data
Dec. 31, 2024 (CN) 202423324264.0

(51) Int. Cl. H05K 1/11

(52) U.S. Cl. CPC H05K 1/111; H05K 2201/10371; H05K 2201/10719

(57) ABSTRACT

A circuit board assembly includes a circuit board, conductive pads attached to a face of the circuit board, a cover, and a locking structure arranged between the cover and the circuit board. The cover and the conductive pads are arranged at a same side of the circuit board. The conductive pads are arranged in an array to form a conductive area. The shape of the cover is adapted to the shape of the conductive area. The locking structure is configured to allow relative movement between the cover and the circuit board for opening and closing the conductive area.

### BACKGROUND OF THE INVENTION

### Field of the Invention

The present invention relates to a circuit board assembly.

### Description of Related Art

LGA (land grid array) packages typically have conductive pads whose surfaces are plated with gold, thus allowing for reliable electrical connections under low contact pressure between the package and the printed circuit board, facilitating high-frequency signal transmission. The gold plating needs protection during operation and transportation.

Therefore, it is necessary to provide a new circuit board assembly to address the above issue.

### SUMMARY OF THE INVENTION

A circuit board assembly comprises a circuit board, conductive pads attached to a face of the circuit board, a cover, and a locking structure arranged between the cover and the circuit board. The cover and the conductive pads are arranged at a same side of the circuit board. The conductive pads are arranged in an array to form a conductive area. The shape of the cover is adapted to the shape of the conductive area. The locking structure is configured to allow relative movement between the cover and the circuit board for opening and closing the conductive area.

A cover is for covering a circuit board which has a face attached with conductive pads arranged in an array to form a conductive area. A shape of the cover is adapted to a shape of the conductive area. The cover includes a locking structure arranged for the cover to move relative to the circuit board for opening and closing the conductive area.

### BRIEF DESCRIPTION OF DRAWINGS

FIG. 1 shows a perspective view of a circuit board assembly according to the present disclosure;

FIG. 2 shows an exploded view of the circuit board assembly of FIG. 1;

FIG. 3 shows an exploded view of the circuit board assembly of FIG. 2 from another perspective; and

FIG. 4 shows a cross-sectional view of the circuit board assembly of FIG. 1 along cut line A-A.

### DETAILED DESCRIPTION OF THE DRAWINGS

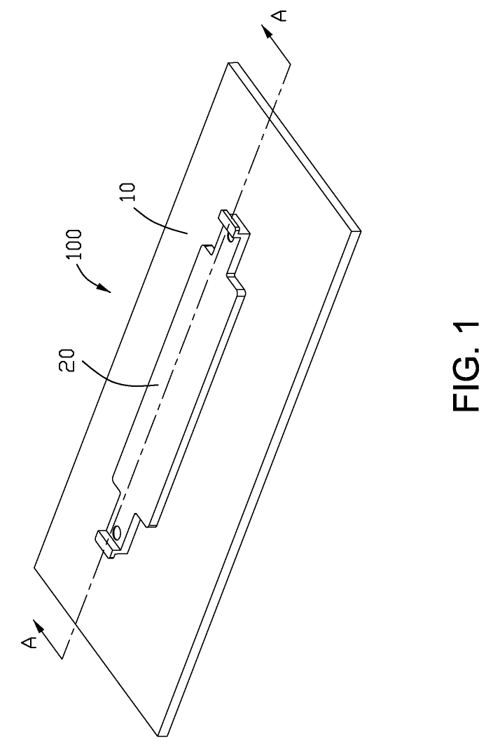

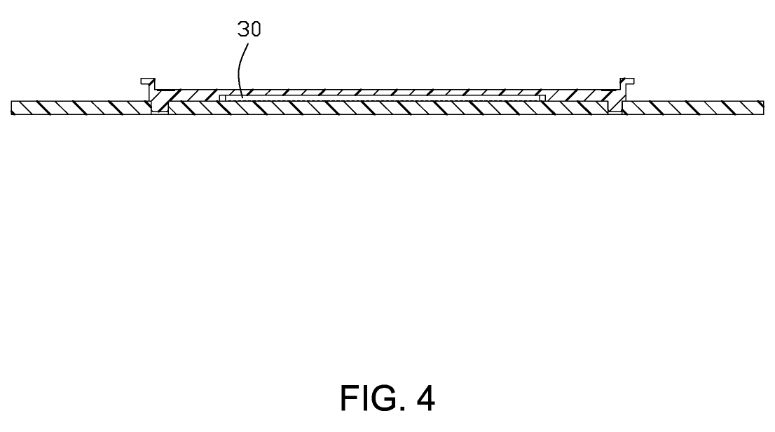

Referring to FIGS. 1-2 and 4, the present disclosure provides a circuit board assembly 100, which is applicable to LGA/LGA sockets and includes a circuit board 10, a plurality of conductive pads 111 attached to a face of a side of the circuit board 10, and a cover 20 on the same side as the conductive pads 111. The conductive pads 111 are arranged in an array to form a conductive area 11. The shape of the cover 20 is adapted to the shape of the conductive area 11. A locking structure is provided between the cover 20 and the circuit board 10, such that the cover 20 can move relative to the circuit board 10 to open and close the conductive area 11. Preferably, surfaces of the conductive pads 111 are plated with gold, and a lower face of the cover 20 has an upwardly formed recess 23. An accommodating space 30 is formed between the recess 23 and the circuit board 10, for accommodating the conductive pads 11. Thus, when the circuit board assembly is in transportation or standby, the conductive pads 111 in the conductive area 11 is effectively protected, preventing accidental scratches to or peeling of the plating. Furthermore, in practice, the opening degree of the cover 20 can be adjusted according to the electrical contact area of a mating connector, to maximize the protection of the conductive area 11.

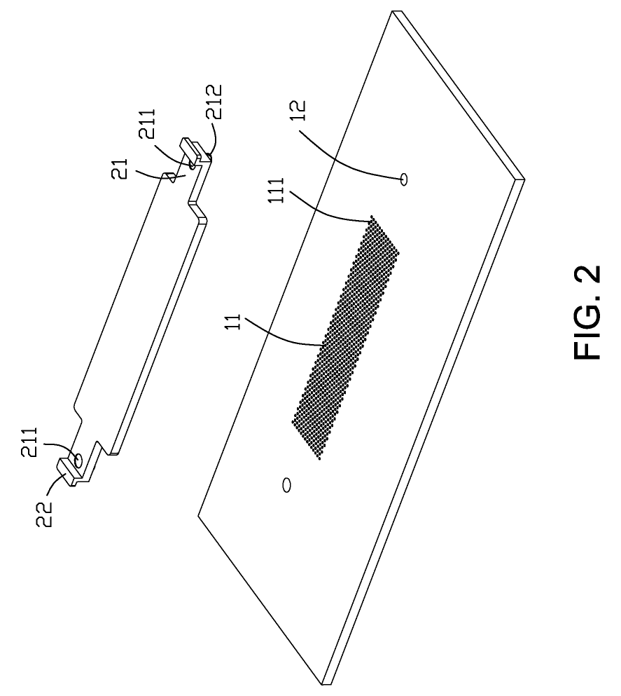

Referring to FIGS. 2-4, at least one side of the cover 20 is formed with an operating portion 21 extending therefrom. The locking structure is connected between the lower surface of the operating portion 21 and the circuit board 10. One of the lower surface of the operating portion 21 and the circuit board 10 has a first engagement portion 212, and the other has a second engagement portion 12 adapted to the first engagement portion 212 to form the locking structure. In the present embodiment, the first engagement portion 212 is a protruding post, the second engagement portion 12 is a positioning hole, each of the two sides of the cover 20 has an operating portion 21 extending therefrom, the free end of each of the operating portions 21 extends upward to form an ear portion 22, the lower surfaces of the operating portions 21 each have a protruding column, and the circuit board 10 has positioning holes. During installation, the two ears 22 can be held to align the protruding posts of the first engagement portions 212 to the positioning holes of the second engagement portions 12, and the two operating portions 21 can be pressed such that the protruding posts engages into the positioning holes to complete the covering.

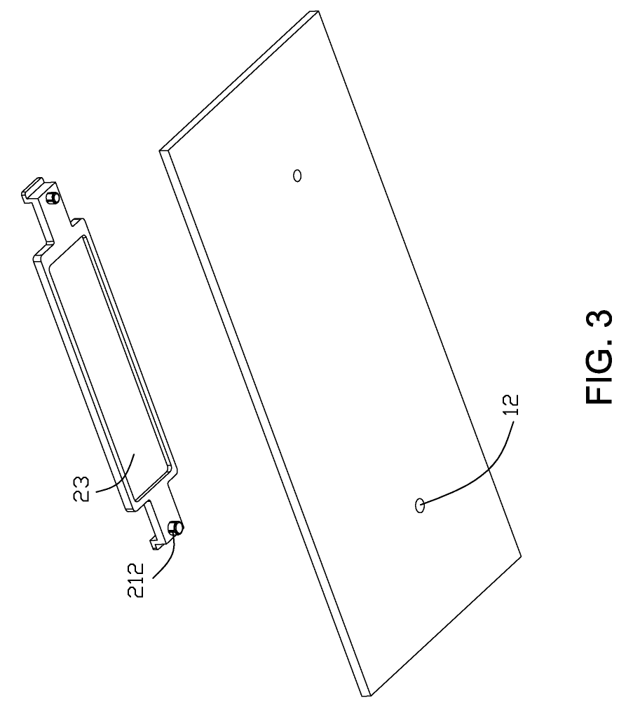

The circuit board assembly 100 typically operates in a confined space. When the cover 20 detachably covers the conductive area 11, the locking structure must have a foolproof effect. Referring to FIGS. 2-3, the first engagement portions 212 on the two sides of the cover 20 have different structures. In the present embodiment, the diameters of the protruding posts are different, such that the cover 20 has a foolproof effect. Preferably, the upper surface of the operating portion 21 has a foolproof mark 211. The shape of the foolproof mark 211 is a cross-section of the corresponding first engagement portion 212. When several circuit board assemblies 100 are joined together, the circuit boards 10 can use different second engagement portions 12. To determine whether the cover 20 has been correctly selected, the shape of the foolproof mark 211 can be observed and determined if it matches the second engagement portion 12.

The above description describes only some embodiments of the present disclosure, and not all embodiments. Any equivalent changes to the technical solution of the present disclosure made by those skilled in the art through reading the present disclosure are covered by the claims of the present disclosure.

1. A circuit board assembly, comprising:
a circuit board;
a plurality of conductive pads attached to a face of the circuit board;
a cover; and
a locking structure, arranged between the cover and the circuit board; wherein
the cover and the conductive pads are arranged at a same side of the circuit board, the conductive pads are arranged in an array to form a conductive area, the shape of the cover is adapted to the shape of the conductive area, and the locking structure is configured to allow relative movement between the cover and the circuit board for opening and closing the conductive area.

2. The circuit board assembly according to claim 1, wherein at least one side of the cover is formed with an operating portion extending therefrom, and the locking structure is connected between a lower face of the operating portion and the circuit board.

3. The circuit board assembly according to claim 2, wherein one of the lower face of the operating portion and the circuit board has a first engagement portion and the other one of the lower face of the operating portion and the circuit board has a second engagement portion adapted to the first engagement portion to form the locking structure.

4. The circuit board assembly according to claim 3, wherein the first engagement portion is a protruding post, and the second engagement portion is a positioning hole.

5. The circuit board assembly according to claim 1, wherein the locking structure has a foolproof effect for facilitating the cover to detachably cover the conductive area.

6. The circuit board assembly according to claim 1, wherein a lower face of the cover is formed with a recess, an accommodating space is formed between the recess and the circuit board, and the conductive pads are accommodated in the accommodating space.

7. The circuit board assembly according to claim 1, wherein the conductive pads are plated with gold.

8. A cover for covering a circuit board which has a face attached with a plurality of conductive pads arranged in an array to form a conductive area, a shape of the cover being adapted to a shape of the conductive area, the cover including a locking structure arranged for the cover to move relative to the circuit board for opening and closing the conductive area.

9. The cover according to claim 8, wherein each of two sides of the cover has an operating portion extending therefrom, a free end of each of the operating portion extends upward to form an ear portion, and one of a lower face of the operating portion and the circuit board has a first engagement portion and the other one of the lower face of the operating portion and the circuit board has a second engagement portion adapted to the first engagement portion to form the locking structure.

10. The cover according to claim 9, wherein the first engagement portions of the operating portions are differently structured for the locking structure to be foolproof to facilitate the cover to detachably cover the conductive area.
